(19) United States
(12) Patent Application Publication
(10) Pub. No.: US 2020/0393308 A1
(43) Pub. Date: Dec. 17, 2020

(54) Fiber Optic Temperature Probe

(71) Applicant: Photon Control Inc., Richmond (CA)

(72) Inventors: Yoshua ICHIHASHI, Richmond (CA); Michael FEAVER, Richmond (CA); Yi LIU, Richmond (CA); Timothy BRAY, Richmond (CA)

(21) Appl. No.: 16/442,420

(22) Filed: Jun. 14, 2019

(51) Int. Cl. G01K 11/32; H01L 21/67

(52) U.S. Cl. CPC G01K 11/32; H01L 21/67248

(57) ABSTRACT

The description pertains to an optical temperature sensor probe having a shaft and a tip. The shaft houses the optical fibers while the tip is made of a thermally conductive material and includes a sensing material therein. The sensing material is in optical communication with the optical fibers of the shaft, however the shaft is spaced from the tip to reduce heat transfer from the tip to the shaft. Furthermore, the sensing material is sealed from the surrounding atmosphere to protect it therefrom. In a preferred embodiment, a window is hermetically sealed to the tip to isolate the sensing material from the environment surrounding the probe.

### FIELD OF THE DESCRIPTION

The description is directed to a temperature sensor. In particular, the description is directed to a fiber optic temperature sensor.

### BACKGROUND

In semiconductor process tools, there is a need for temperature control and monitoring to understand and maintain process control. A limited selection of materials can to be used within chambers to avoid contamination of the chamber and degradation of the sensor materials exposed to the process environment. In addition, specific applications reach high temperatures and require materials to survive over 300° C. Fiber optic temperature sensors used in such applications require careful material selection and unique design considerations.

Phosphor material used inside temperature sensor probes are exposed to the harsh environments with high temperatures and corrosive chemicals. This results in a change or loss of measurement over time as the phosphor is attacked and degrades. The phosphor must be protected from the environment to ensure long term reliability of the temperature sensor measurement systems. The mechanical design of the probe must consider protection of the phosphor from the environment containing at least plasma and fluorine at temperatures up to or above 300° C.

Minimizing the difference in temperature between the phosphor and target surface enables more accurate measurement. For contact temperature sensors, this can be achieved by minimizing the heat loss from the contact tip and maximizing the contact between the tip and the measurement surface.

A unique solution is required to achieve accurate contact temperature measurement at high temperatures in semiconductor process environments. To achieve this the objective of the design will be to protect the sensing material from the process environment, reduce the heat loss from the tip to improve contact measurement accuracy, and maximize the material selection in the high temperature and semiconductor process environment.

### SUMMARY OF THE DESCRIPTION

The description pertains to an optical temperature sensor probe having a shaft and a tip. The shaft houses the optical fibers while the tip is made of a thermally conductive material and includes a sensing material therein. The sensing material is in optical communication with the optical fibers of the shaft, however the shaft is spaced from the tip to reduce heat transfer from the tip to the shaft. Furthermore, the sensing material is sealed in such a way that it is isolated from the surrounding atmosphere. In a preferred embodiment, a window is hermetically sealed to the tip to isolate the sensing material from the environment surrounding the probe.

In one aspect, there is provided an optical temperature probe comprising a shaft and a tip. The shaft has a channel therethrough to house optical fibers which terminate at a distal end of the shaft. The tip has a thermally conductive body and an optically excited sensing material. The sensing material is in optical communication with the end of the optical fibers at the distal end of the shaft and sealed from a surrounding atmosphere. Furthermore, the tip is spaced from said shaft.

In another aspect, the tip further comprises a window located between the distal end of the shaft and the tip.

In yet another aspect, the window is hermetically sealed to the thermally conductive body of the tip

In yet a further aspect, the window is sealed to the thermally conductive body using an adhesive having structural stability at temperatures over 300° C.

In yet a further aspect, the adhesive is resistant to corrosion from radicals.

In yet another aspect, the window and the thermally conductive body have similar coefficients of thermal expansion.

In yet another aspect, the window is sealed to the thermally conductive body using zinc borosilicate.

In yet another aspect, the thermally conductive body of the tip includes a shoulder extending above and around the optically excited sensing material and the adhesive is applied between the shoulder and the window.

In yet another aspect, an air gap is present between the sensing material and a bottom surface of the window.

In yet another aspect, the thermally conductive body is made of alumina.

In yet another aspect, the window is made of sapphire.

In yet another aspect, the optically excited sensing material is phosphorescent.

In yet another aspect, the optically excited sensing material is phosphor.

In another aspect, there is provided a measurement system for determining the temperature of an object in a semiconductor chamber comprising an optical temperature probe and a showerhead. The optical temperature probe comprises a base, a shaft extending from the base and a tip longitudinally spaced from the shaft. The shaft has a channel therethrough to house optical fibers, which terminate at a distal end of the shaft. The tip comprises a thermally conductive body and an optically excited sensing material. The optically excited sensing material is in optical communication with the optical fibers and is sealed from a surrounding atmosphere. The showerhead is adapted to be coupled to the base of the optical temperature probe and further configured to support the tip such that a first portion of the thermally conductive body of the tip is in contact with the object of which the temperature is to be determined. Furthermore, the base and the showerhead are coupled in a manner such that a seal is maintained therebetween.

In another aspect, the semiconductor chamber is a deposition chamber.

In yet another aspect, the semiconductor chamber is an etch chamber.

In yet another aspect, the showerhead is further configured to support the tip of the optical temperature probe such that a the optically excited sensing material of said tip shares a common longitudinal axis with the shaft.

### BRIEF DESCRIPTION OF THE FIGURES

The features of certain embodiments will become more apparent in the following detailed description in which reference is made to the appended figures wherein:

FIG. 1 is a schematic illustration of the temperature probe, optical cable and temperature sensor converter;

FIG. 2 is a schematic illustration further depicting some of the interior components of the temperature sensor converter;

FIG. 3 is a cross-sectional top perspective view of the temperature probe;

FIG. 4 is a cross-sectional view of the temperature probe mounted to a showerhead of a semiconductor deposition chamber;

FIG. 5 is a cross sectional view of the tip; and

FIG. 6 is a perspective view of the tip.

FIG. 7 is a cross sectional view of the top showing the adhesive between the window and the body.

### DETAILED DESCRIPTION

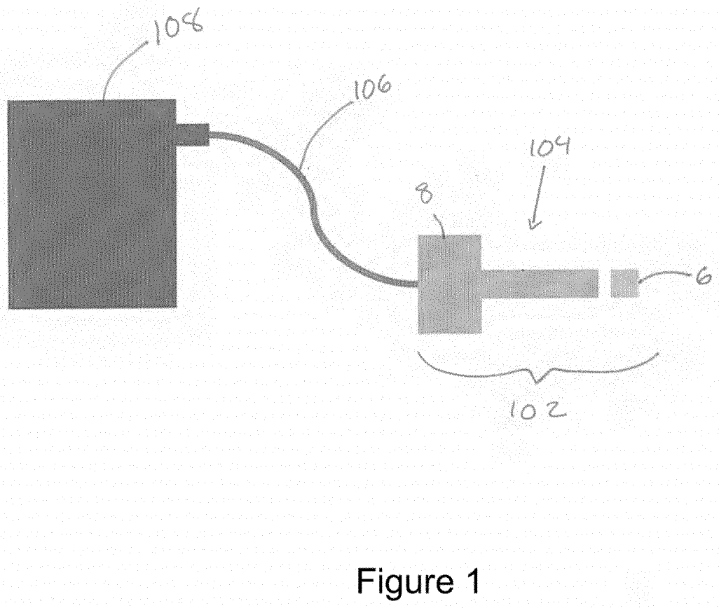

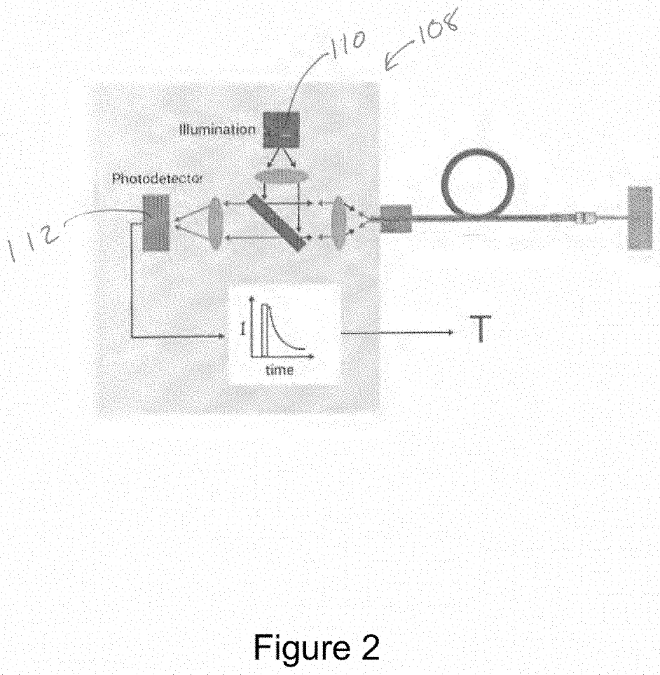

FIG. 1 shows an optical temperature sensor having a temperature probe 102, comprising a tip 6 and a mount 104. The mount 104 contains a fiber optical cable 106 therein and this fiber optical cable 106 extends out from the mount 104 to optically couple the mount 104 to a temperature sensor converter 108. As illustrated in FIG. 2, the temperature sensor converter 108 contains therein, an illumination device 110 for providing a light source to be projected down the fiber optical cable 106 and a photodetector 112 to receive

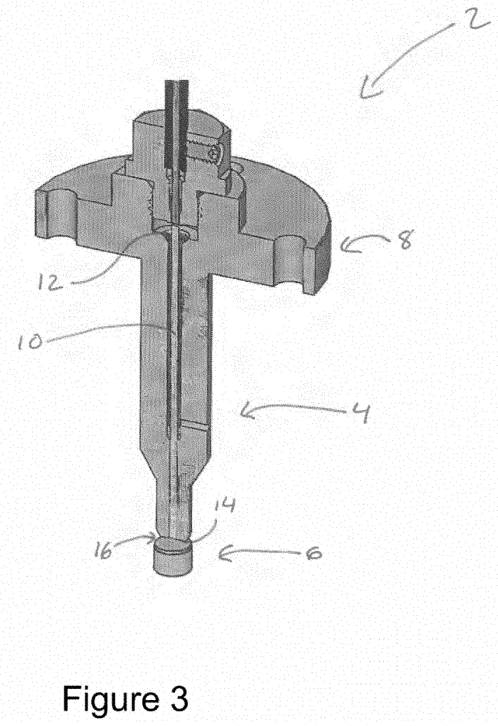

FIG. 3 illustrates a fiber optic temperature sensor 2 having a shaft 4, a tip 6, and a base 8. Optical fibers 10, making up optical cable 106, run through a channel 12 in the shaft 4 and base 8. Although various types of optical fibers would be known to a person skilled in the art, in a preferred embodiment, the fiber is a fused silica fiber with a silica cladding. While various sizes of fibers would be known, in a preferred embodiment, the fiber has a 1 mm diameter. The optical fiber 10 is exposed at the bottom end 14 of the shaft 4. Below the shaft 4, and spaced from the shaft 4, is the tip 6. Since the tip 6 is spaced from the shaft 4, the space between the shaft and the tip is filled with the atmosphere of the environment in which the sensor is being used. Preferably, the space, or gap 16, between the shaft 4 and tip 6 is approximately, 0.25 to 1.5 mm wide. It can be appreciated by a person skilled in the art that this distance can vary. By increasing the power of the light source, an increased distance between the optical fibers 10 and the tip can be used.

The optical fibers 10 are held in place by the base 8 and shaft 6, however the illumination device 110, photodetector 112 and means for processing the light and wavelength returning to the temperature sensor converter 108 are preferably be located external to probe 102, as shown in FIG. 2. The optical fibers 10 extend outside the probe 102 as part of optical cable 106. In this way, the light source and means for processing a light signal can be located away from the any harsh environment in which the temperature sensor is being used.

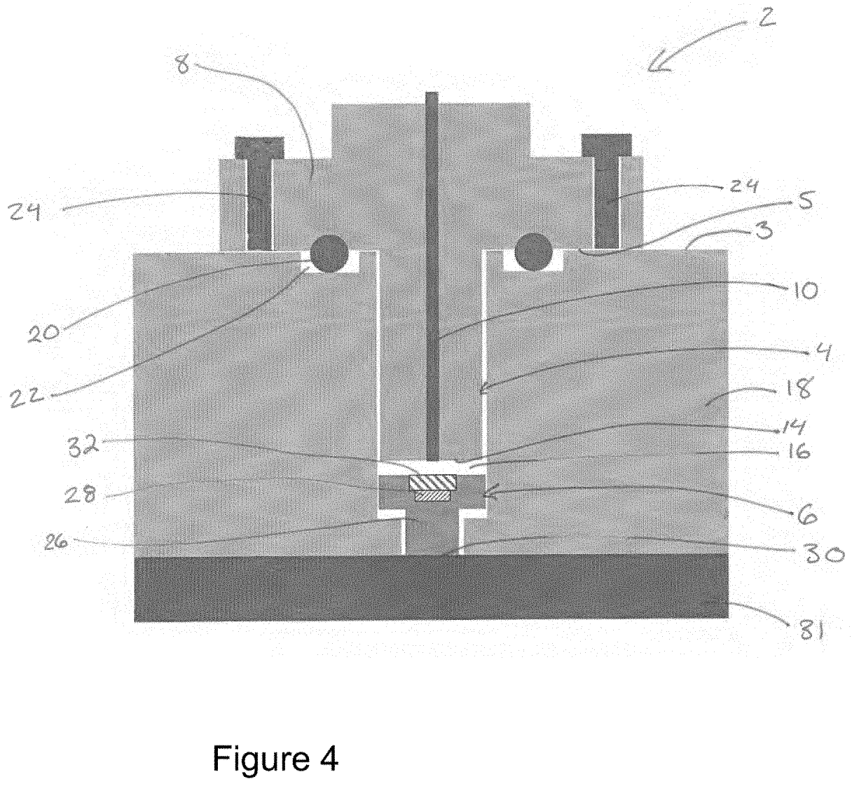

FIG. 4 shows the temperature sensor 2 fixed to the body of a showerhead for use in semiconductor environments. While the temperature sensor described herein could be used in a variety of environments, due to the harsh nature of semiconductor chambers, the temperature sensor 2 has particular advantages for use in semiconductor environments, for example in semiconductor deposition chambers or semiconductor etch chambers. However, it will be appreciated by a person skilled in the art that the temperature sensor 2 could be used in any environment suitable for a contact optical temperature sensor. As such, the design of the base 8 can be varied to be suitable for use in any environment where an optical contact temperature sensor is required.

Returning to FIG. 4, the temperature sensor 2 is coupled to the body of the showerhead 18. In order to maintain a firm seal with the showerhead 18 a sealing device, such as the O-ring 20 is compressed between the top surface 3 of showerhead 18 and the bottom surface 5 of base 8. As can be appreciated, other methods of sealing would be known to a person skilled in the art. This seal is used to maintain the vacuum in the semiconductor chamber. However, in other applications where a sealed air-tight environment is not required, the seal can be omitted. The O-ring 20 sits in groove 22 of the showerhead 18 to provide proper positioning of the O-ring 20 relative to the sensor base 8 and to allow for ease of assembly without the O-ring 20 shifting. The base 8 is then preferably fixed to the showerhead 18 using screws 24. Although screws are shown as a preferred method of coupling the base 8 to the showerhead 18, a person skilled in the art would know that other methods of coupling could be used. While only 2 screws 24 are shown in the figures as points of attachment, it can be appreciated that any suitable number of points of attachment could be used.

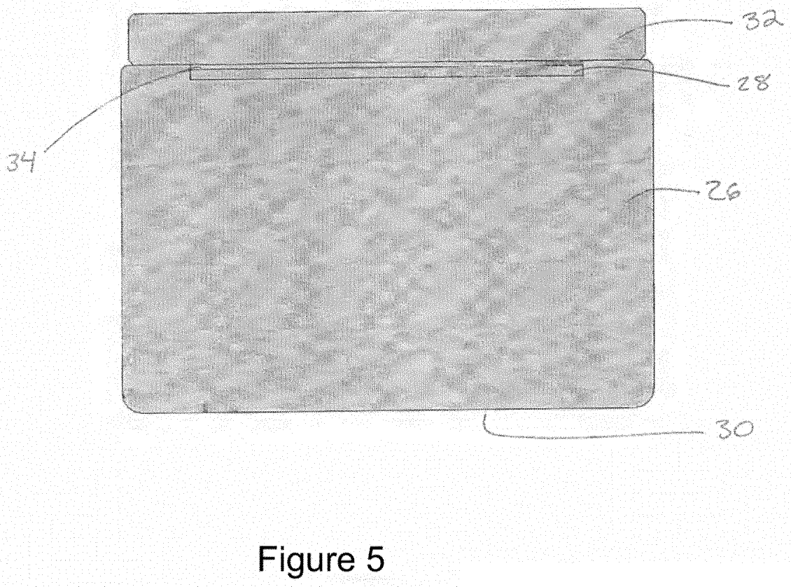

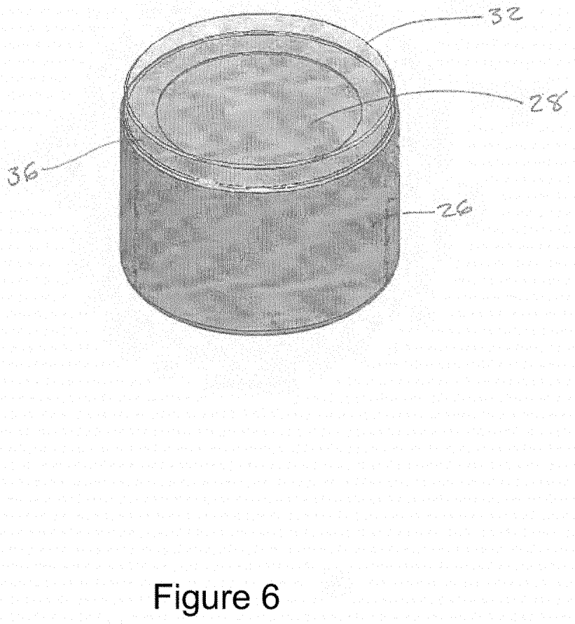

The tip 6, shown in FIGS. 5 and 6, has a body 26 made of a thermally conductive material. In a preferred embodiment, the body 26 is made of alumina. While other suitable materials may be known to a person skilled in the art, alumina allows for good conductivity while being resistant to high temperatures and corrosive environments, such as those in semiconductor deposition chambers containing plasma and other chemicals such as, Fluorine.

Within the tip 6 is a layer of sensing material 28. This sensing material is preferably phosphorescent and in the preferred embodiment is phosphor, although other materials would be known to a person skilled in the art.

The sensing material 28 is applied onto the thermally conductive tip. In order to do this the sensing material is mixed with a suitable adhesive, which would be known to a person skilled in the art. Application of the sensing material and adhesive combination can be done by any suitable method known to a person skilled in the art including, but not limited to deposition, sputtering, bonding, panting, and spin on. The sensing material 28 is excited by light transmitted through optical fibers. As stated above, the body material 26 is thermally conductive to increase the heat flow from the measurement surface 30 to the sensing material 28 for more accurate measurement.

The sensing material 28 can be protected from the environment using a window 32 positioned between the sensing material 28 and the gap 16. The window 32 is sealed to the body 26 of the tip 6 using any suitable sealing process that will hermetically seal the window 32 between the body material 26 and the gap 16. In a preferred embodiment an adhesive having high temperature resistance and resistance to radicals is preferred. The window 32 is transparent to allow for light to be transmitted from the optical fibers 10 to the sensing material 28. Although a variety of materials could be used for the window, the preferred material is sapphire as it is highly transparent, compatible with the preferred hermetic sealing technique (described below), capable of surviving high temperature environments and resistant to the harsh chemical environment of a semiconductor chamber. Furthermore, sapphire and alumina have similar coefficients of thermal expansion and thus a seal can be maintained between the two even as the temperature changes. In this respect, similar coefficients of thermal expansion can be defined as coefficients of thermal expansion which are sufficiently similar such that when window material and body material expand and contract, the rates and amount of expansion and contraction are not so different as to cause separation between the two. Typically, materials wherein the difference in coefficients of thermal expansion is in the range of 6-10×10⁻⁶° C. or less will be suitable. It can be appreciated by a person skilled in the art that other window and tip materials with similar coefficients of thermal expansion could be used.

As can be seen in FIG. 4, the body 26 of the tip 6 has a shoulder or sealing surface 36 to allow for the sealing of the window 32 to the body 26 without contacting the sensing material 28. The outer edges of the window 32 are preferably affixed to the body 26 using zinc borosilicate glass due to its ability to adhere to both sapphire and alumina and maintain adhesion in high temperature applications. Although zinc borosilicate glass is used as an adhesive in a preferred embodiment, other adhesives would be known to a person skilled in the art.

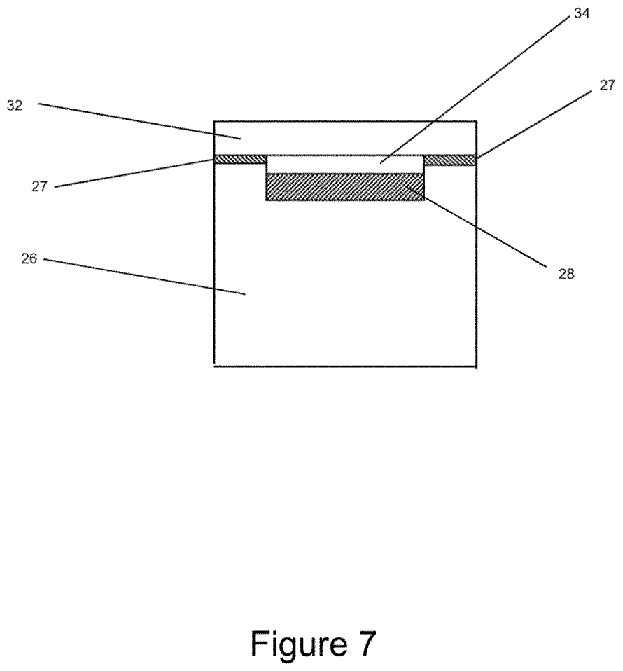

Using the preferred embodiment as an example, in order to create the hermetic seal, the adhesive, for example zinc borosilicate glass, is heated. For zinc borosilicate glass, it is heated to approximately 400° C. to 700° C. A film of the adhesive is applied to the sapphire, or alumina, or both the sapphire and alumina, using any suitable method, including, but not limited to, chemical vapor deposition, sputtering, evaporating and spin on. FIG. 7 shows the sealing material 27 between the window 32 and the body 26.

In a preferred embodiment, the application of the glass seal can be screen printed or painted onto the surface. A stencil is made with a geometry adapted to fill the volume of space between the sensing material and the sealing surface. The glass seal is applied, and the stencil is removed. The window is then placed atop the adhesive using a fixture to ensure concentricity between the window to the tip. The entire assembly is then placed in a furnace and baked at atmospheric pressure.

A layer of gas 34, preferably air, is left between the sensing material 28 and the window 32. This layer of gas 34 ensures that the sensing material 28 does not touch the window 32. Thus, the sensing material 28 can not lose heat to the window which aids in more accurate temperature measurements.

The window is directly sealed onto the probe tip in which the sensing material is applied. By sealing the window in the probe tip, the tip assembly is self contained and can be used for various tip geometries to maximize contact and heat transfer from the measured surface.

In an alternative embodiment a transparent coating of sapphire or other suitable material, such as aluminum oxide, is applied on to the upper surface of the body of the tip to completely cover the sensor material, isolating the sensor material from the surrounding environment. This could be done with a variety of different methods such as, but not limited to, deposition, screen printing or with a thermal spray coating process.

When in use, the tip is placed in contact with the material for which the temperature reading is required. Since the body 26 of the tip 6 is made of conductive material, the heat flows from the measurement surface 31 through the body 26 of the tip 6 and into the sensing material 28. A light signal from the illumination device (shown in FIG. 2) is sent down the optical fibers. The light shines through the transparent window 32 and on to the sensing material 28. The incoming light excites the sensing material causing it to emit a wavelength of light back through the window and into the optical fibers 10. This light is transmitted through the optical cable 106 to the temperature sensor converter 108. Since the wavelength emitted by the sensing material 28 is correlated to the temperature of the sensing material 28, the temperature sensor converter 108 uses the wavelength to determine the temperature of the sensing material 28 which is reflective of the temperature of the measurement surface 31. In the preferred embodiment that has a tip body material of alumina and a window material of sapphire, temperature can be measured with an accuracy of approximately +/−2° C.

By separating the tip 6 from the shaft 4, heat loss from the tip to the shaft is reduced compared to traditional optical temperature sensors. This improves the accuracy of the measurement by reducing the difference in the temperature of the sensing material 28 and the measurement surface 31. Furthermore, since the optical fibers are spaced from the tip, heat transfer from the tip to the optical fibers is reduced. This allows materials which have a lower temperature tolerance to be used to make the optical fibers, reducing cost. Furthermore, the number of parts required for assembly is also reduced. By isolating the sensor material from the surrounding harsh environment, durability of the probe is increased, and should the tip eventually degrade, it would be potentially possible to replace just the tip as opposed to the entire probe.

Although the above description includes reference to certain specific embodiments, various modifications thereof will be apparent to those skilled in the art. Any examples provided herein are included solely for the purpose of illustration and are not intended to be limiting in any way. Any drawings provided herein are solely for the purpose of illustrating various aspects of the description and are not intended to be drawn to scale or to be limiting in any way. The scope of the claims appended hereto should not be limited by the preferred embodiments set forth in the above description, but should be given the broadest interpretation consistent with the present specification as a whole. The disclosures of all prior art recited herein are incorporated herein by reference in their entirety.

We claim:

1. An optical temperature probe comprising;
a shaft and a tip;
said shaft having a channel therethrough to house optical fibers, said optical fibers terminating at a distal end of the shaft;
said tip comprising a thermally conductive body and an optically excited sensing material;
said optically excited sensing material being in optical communication with said optical fibers and sealed from a surrounding atmosphere; and
wherein said tip is spaced from said shaft.

2. The temperature probe of claim 1 wherein the tip further comprises a window located between said distal end of said shaft and said tip.

3. The temperature probe of claim 2 wherein the window is hermetically sealed to the thermally conductive body of the tip.

4. The temperature probe of claim 2 wherein the window is sealed to the thermally conductive body using an adhesive having structural stability at temperatures over 300° C.

5. The temperature probe of claim 4 wherein the adhesive is resistant to corrosion from radicals.

6. The temperature probe of claim 5 wherein said window and said thermally conductive body have similar coefficients of thermal expansion.

7. The temperature probe of claim 2 wherein the window is sealed to the thermally conductive body using zinc borosilicate.

8. The temperature probe of claim 1 wherein said thermally conductive body of said tip includes a shoulder extending above and around the optically excited sensing material and said adhesive is applied between said shoulder and said window.

9. The temperature probe of claim 8 wherein an air gap is present between said sensing material and a bottom surface of said window.

10. The temperature probe of claim 1 wherein the optically excited sensing material is phosphorescent.

11. The temperature probe of claim 7 wherein the thermally conductive body is made of alumina, and the window is made of sapphire.

12. A measurement system for determining the temperature of an object in a semiconductor chamber comprising,
an optical temperature probe and a showerhead;
said optical temperature probe comprising;
a base, a shaft extending from said base and a tip longitudinally spaced from the shaft;
said shaft having a channel therethrough to house optical fibers, said optical fibers terminating at a distal end of the shaft;
said tip comprising a thermally conductive body and an optically excited sensing material;
said optically excited sensing material being in optical communication with said optical fibers and sealed from a surrounding atmosphere;
said showerhead is adapted to be coupled to said base of said optical temperature probe;
said showerhead further configured to support said tip such that a first portion of the thermally conductive body of the tip is in contact with the object of which the temperature is to be determined; and
wherein said base and said showerhead are coupled in a manner such that a seal is maintained therebetween.

13. The system of claim 12 wherein the window is sealed to the thermally conductive body using an adhesive having structural stability at temperatures over 300° C.

14. The system of claim 13 wherein the adhesive is resistant to corrosion from radicals.

15. The system of claim 14 wherein said window and said thermally conductive body have similar coefficients of thermal expansion.

16. The system of claim 15 wherein the semiconductor chamber is a deposition chamber.

17. The system of claim 15 wherein the semiconductor chamber is an etch chamber.

18. The system of claim 15 wherein said thermally conductive body of said tip includes a shoulder extending above and around the optically excited sensing material and said adhesive is applied between said shoulder and said window.

19. The system of claim 18 wherein an air gap is present between said sensing material and a bottom surface of said window.

20. The system of claim 15 wherein said showerhead is further configured to support said tip of said optical temperature probe such that a the optically excited sensing material of said tip shares a common longitudinal axis with the shaft.
